(19) United States
(12) Patent Application Publication
(10) Pub. No.: US 2010/0156251 A1
(43) Pub. Date: Jun. 24, 2010

(54) PIEZOELECTRIC ACTUATOR AND METHOD FOR PRODUCING IT

(76) Inventors: Eugen Hohmann, Viereth-Trunstadt (DE); Stefan Henneck, Leonberg (DE); Immanuel Fergen, Bruchsal (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/297,507

(22) PCT Filed: Apr. 18, 2007
(86) PCT No.: PCT/EP2007/053751

§ 371 Date: Oct. 17, 2008

(30) Foreign Application Priority Data
Apr. 19, 2006 (DE) 10 2006 018 034.8

(51) Int. Cl. H01L 41/047; H01L 41/22; H01L 41/083

(52) U.S. Cl. 310/364; 29/25.35; 29/851; 310/366

(57) ABSTRACT

The invention relates to a method for producing a piezoelectric actuator in which a metallization paste is applied to a sintered piezoelectric stack and a flexible metal electrode is arranged on top of the paste. In a subsequent baking or firing step, a base metallic coating is formed from the metallization paste, whereby the base coating is permanently connected to the piezoelectric stack and to the flexible metal electrode. Alternatively, the metallization paste can be applied to a green body which is subsequently sintered so that a first layer of a base metallic coating is formed in the sintering step. A metallization paste is applied to the first layer in a similar manner and a flexible metal electrode is arranged thereon, whereby the metal electrode becomes fixed during a second baking step.

### PRIOR ART

The invention is based on a piezoelectric actuator of the kind known for instance from published German Patent Application DE 199 28 189 A1. A piezoelectric actuator of this kind is embodied as a multilayer actuator; that is, it comprises a multiplicity of piezoelectrically active ceramic layers. Between these layers, metal inner electrodes are embodied two-dimensionally, which extend in alternation into a region of the surface. There, the inner electrodes are put into contact with at least two outer electrodes, by means of which an electrical voltage can be applied to the inner electrodes in such a way that between respective adjacent inner electrodes, an electrical field is created that penetrates the piezoelectrically active layers. Depending on the intensity of the electrical field, that is, the magnitude and polarity of the electrical voltage applied, the thickness of the piezoceramic layers varies, which as a whole causes a change in length of the piezoelectric actuator.

The outer electrodes here comprise a base metallization, which is applied directly to the piezoelectric actuator, and a flexible metal electrode, which is usually meshlike or clothlike and which is soldered to the base metallization. The reason for this is that because of the change in length of the piezoelectric actuator, the directly applied base metallization can tear, and then a continuous introduction of the electrical voltage into the inner electrodes would no longer be assured. By means of the flexible metal electrode, which is bonded to the base metallization at various points, the electrical voltage is nevertheless introduced, even if tears occur in the base metallization, so that all the inner electrodes are supplied with the applicable electrical voltage.

In the production of the piezoelectric actuator, so-called green sheets are first stacked, until a piezoelectric stack with the desired number of piezoelectric layers and associated inner electrodes is formed. The piezoelectric stack is then sintered, so that a hard ceramic forms. For applying the base metallization, the so-called sintered skin that is formed by the sintering process on the surface of the piezoelectric stack must first be removed. If this production-caused electrically insulating layer is not removed, electrical contacting of the inner electrodes would no longer be possible, or would be possible only unsatisfactorily. Once the sintered skin has been removed, the two-dimensional base metallization is applied. This can be done by various methods, such as sputtering, galvanic deposition, or imprinting a metallizing paste and firing it, this last method being the most favorable from the standpoint of process technology.

As the metal component for the base metallization, silver or a silver-palladium alloy is predominantly employed. Still other substances are also admixed with the metallizing paste, which serve as adhesion promoters, and without which a secure bond between the completely sintered piezoelectric ceramic and the base metallization would not be possible. After the firing of the base metallization thus obtained, the flexible metal electrode is typically applied by soldering. However, this is an additional, expensive and difficult process step, since after the soldering process an intensive cleaning process using organic solvents is necessary to remove the residues of flux. This makes the piezoelectric actuator, and thus its possible applications in the field of direct diesel injection, more expensive.

### DISCLOSURE OF THE INVENTION

### Advantages of the Invention

The method according to the invention for producing a piezoelectric actuator, which has a multiplicity of piezoelectrically active ceramic layers and corresponding metal inner electrodes, has the advantage over the prior art that the base metallization and the flexible metal electrode are bonded to the piezoelectric stack by means of a single process step. The method is subdivided into two alternatives: In the first alternative, the piezoelectric stack is formed of green sheet and then sintered. The sintered piezoelectric stack is sanded off, and the base metallization is applied in a first layer to the sanded parts. After the first layer dries, a second layer is applied, onto which, while the second layer is still liquid, the flexible metal electrode is placed. Next, the piezoelectric actuator is fired, so that on the one hand the second layer of the base metallization bonds to the first layer, and on the other, the flexible metal electrode bonds to the base metallization.

In the second alternative of the method, the first layer of the base metallization is already applied to the green body, that is, to the piezoelectric stack formed by the green sheet. Next, the green body is sintered, producing a hard ceramic, whereupon the first layer of the base metallization already bonds to the surface of the piezoelectric stack. By means of this base metallization, the development of a sintered skin at this point is prevented, so that the ensuing sanding of the piezoelectric actuator is dispensed with. Next, a second layer of the metallizing paste is applied, which forms the second layer of the base metallization. Once again the flexible outer electrode is placed on this wet layer, and after the wet layer has dried, the flexible metal electrode is bonded to the base metallization by a firing process.

In advantageous refinements of the method of the invention, the firing is effected at a temperature of preferably more than 300° C. This is preferably done under protective gas, such as nitrogen, argon, or some other noble gas, so that oxidation of the metal electrode is prevented. If the metallizing paste that forms the base metallization is liquid when the flexible outer electrode is applied, then a meniscus forms at the contact points of the flexible metal electrode, so that after the firing, a mechanically heavy-duty bond that is highly electrically conductive is created between the flexible metal electrode and the base metallization.

In a further advantageous refinement of the method of the invention, the second layer of the base metallization is applied to only from 20 to 80%, and preferably 30 to 70%, of the first layer. This second layer is preferably applied in parallel strips, which are tilted relative to the plane perpendicular to the expansion direction of the piezoelectric stack. This has the advantage of creating regions that have a relatively great layer thickness of the base metallization and accordingly are less affected by cracks in the base metallization. If cracks do occur in the base metallization, then this preferentially occurs precisely parallel to the piezoelectrically active layers, and these cracks propagate into the first layer of the base metallization, where they lead to an interruption of the mechanical bond and hence of the electrical conduction. However, because of the strips of the second layer that are bonded to the flexible metal electrode, the electrical voltage is conducted into all the regions of the base metallization, and this is assured by the angle formed between the parallel strips of the second layer and the plane perpendicular to the expansion direction of the piezoelectric stack.

The piezoelectric actuator produced by the method of the invention is likewise the subject of the present invention. The flexible metal electrode is fired into the base metallization, so that the otherwise usual soldering process can be dispensed with.

The flexible metal electrode is preferably embodied such that as a result of the firing, it is bonded only to the second layer of the base metallization. The pattern of the second layer of the base metallization in the form of strips as already mentioned above with regard to the method of the invention is especially advantageous here as well. To achieve a good electrical connection between the flexible metal electrode and the base metallization, it is especially advantageous to use a metal electrode of Invar that is silver-plated. Invar is a metal alloy which has an especially slight thermal expansion and is thus approximately the same as the piezoelectric ceramic. As a result, only slight mechanical stresses occur from temperature fluctuations to which the piezoelectric actuator is necessarily exposed in use in an internal combustion engine. The silver-plating of the Invar assures a good bond between the flexible metal electrode and the base metallization, the latter preferably comprising silver or a silver-palladium alloy.

### DRAWINGS

In the drawings, a piezoelectric actuator of the invention and various process steps of the method for its production are shown.

FIG. 1 schematically shows a piezoelectric actuator of the invention in an elevation view;

FIG. 2 is a side view of the piezoelectric actuator in a first process step;

FIGS. 3, 4 and 5 show the subsequent process steps in the production of the piezoelectric actuator; and

FIG. 6 is a cross section through a piezoelectric actuator of the invention.

### EMBODIMENTS OF THE INVENTION

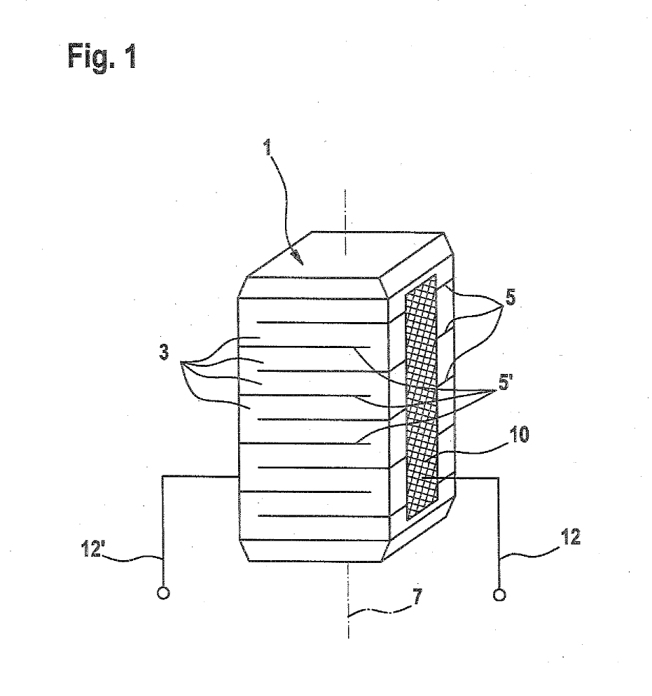

In FIG. 1, a piezoelectric actuator of the invention is shown schematically in a perspective view. The piezoelectric actuator has a piezoelectric stack 1, which comprises a multiplicity of piezoelectric layers 3. For the sake of clarity, only a few piezoelectric layers 3 are shown in FIG. 1. Actual piezoelectric actuators usually have from 100 to 200 such piezoelectric layers 3. Between each two piezoelectric layers is a metal inner electrode 5 or 5′, and these metal inner electrodes extend in alternation to one side or the other of the piezoelectric stack. Half of the inner electrodes 5, 5′ are electrically contacted by an outer electrode 10, 10′ that is applied to the surface of the piezoelectric stack 1. The outer electrode 10 comprises a base metallization 20, which is applied directly to the surface of the piezoelectric stack 1, and a sievelike or meshlike flexible metal electrode 25, which is bonded to the base metallization 20. The flexible metal electrode 25 is finally connected to an electrical terminal 12, 12′, by way of which an electrical voltage can be applied.

By the application of the electrical voltage between the electrical terminals 12, 12′, an electrical field is created between the inner electrodes 5 extending to the outside on side of the piezoelectric stack 1, and other half of the inner electrodes 5′, which extend as far as the surface on the opposite side of the piezoelectric stack 1. A relatively homogeneous electrical field that penetrates the piezoelectric layers 3 is thus obtained between the inner electrodes 5, 5′. Depending on the intensity and polarity of this electrical field, a change in thickness of the piezoelectric layers 3 hence an overall change in the length of the piezoelectric stack 1 takes place. The piezoelectric stack 1 expands or contracts along an axis of expansion 7; the direction of the axis of expansion 7 is determined by way of the direction of polarization of the piezoelectric ceramics.

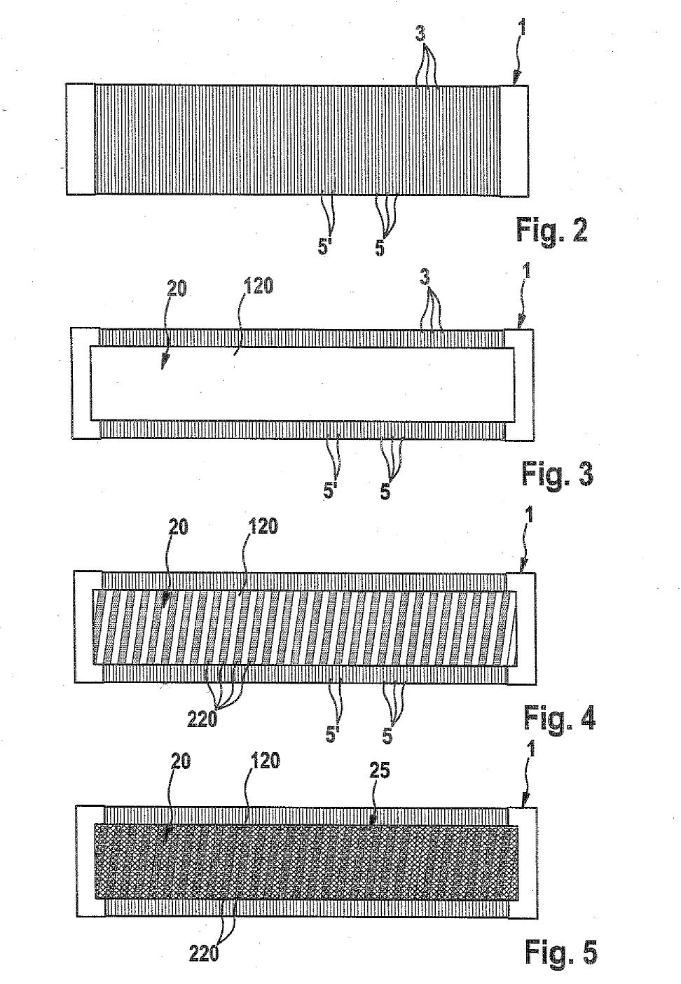

The production of the piezoelectric actuator is done by the following method: For forming the piezoelectric actuator, green sheet is stacked and laminated. The green sheet comprises a piezoelectric ceramic powder with a polymer binder mixture that is provided with a metal pressure layer, so that a stack with alternating piezoelectrically active ceramic layers and metal electrodes is created, the so-called green body. Next, the green body is debindered and sintered, or in other words fired at high temperatures, so that the organic polymer binder volatilizes, and the ceramic powder is converted into a solid, densified ceramic that in the final analysis is piezoelectrically active. FIG. 2 for this purpose shows a top view on the thus-created piezoelectric stack 1, in which the disposition of the piezoelectric layers 3 and the inner electrodes 5 and 5′ is clearly shown. In piezoelectric actuators of the kind used in fuel injection systems, often more than two hundred piezoelectric layers 3 are usual. The layer thickness of the individual piezoelectric layers 3 is approximately 0.1 mm, while the inner electrodes 5, 5′ have a layer thickness of only a few μm.

For applying the base metallization, the piezoelectric stack 1 is sanded after sintering, in order to remove the sintered skin that would otherwise make an electrical contact with the inner electrodes 5, 5° more difficult or even impossible. Next, a metallizing paste is applied, which forms a first layer 120 of the base metallization 20. FIG. 3 with regard to this shows this first layer 120 of the base metallization 20, which covers the full surface of one side of the piezoelectric stack 1. The metallizing paste is liquid on being applied, so that before the further process steps, there is a wait until this first layer 120 has dried. Next, a second layer 220 of the base metallization 20 is applied, as shown in FIG. 4. This second layer 220 is applied in strips that are inclined obliquely to the axis of expansion 7 of the piezoelectric stack 1. The second layer of the base metallization 20 covers from 20 to 80% of the first layer 120, and preferably from 30 to 70%.

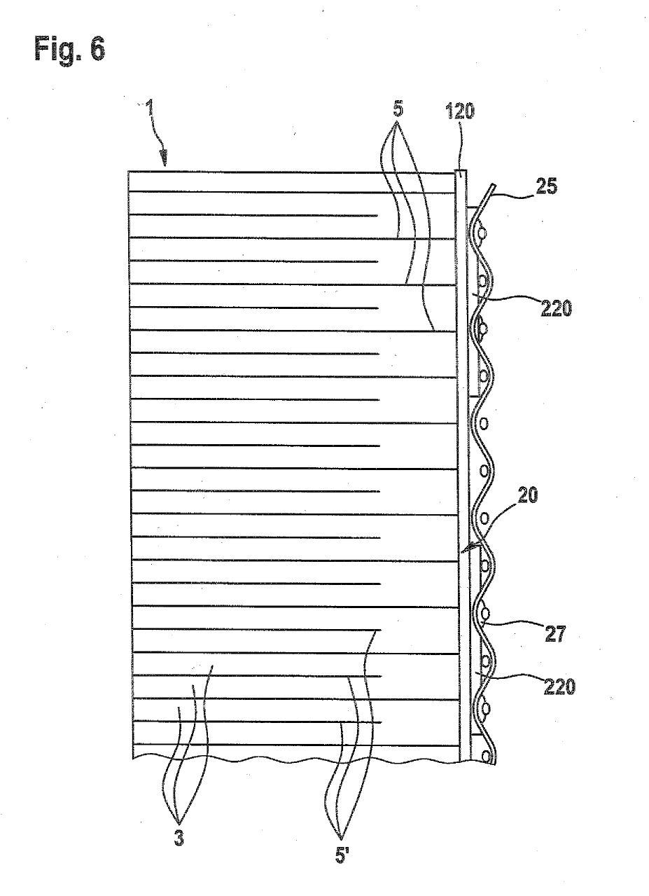

In the next process step, a flexible metal electrode 25 is placed in the still-liquid second layer 220 of the base metallization 20, as shown in FIG. 5. The flexible metal electrode 25 may be formed of wire in meshlike or sievelike fashion, preferably Invar wire, since that has an only slight thermal expansion that is similar to that of ceramic. Since the second layer 220 of the base metallization 20 is still liquid, a meniscus 27 forms at the contact points of the flexible metal electrode and establishes a good electrical connection of the flexible metal electrode 25 with the second layer 220 of the base metallization 20. FIG. 6 in this regard shows a cross section through the piezoelectric stack 1 in which this effect is shown clearly.

By the application of the second layer 220 of the base metallization 20 in strips, electrical contact between the flexible metal electrode 25 and the base metallization 20 occurs only at those points. The flexible metal electrode 25 and the base metallization 20 together form the outer electrodes 10, 10′. In order to fix the outer electrodes 10, 10′, the piezoelectric stack 1 is then fired, so that the flexible metal electrode 25 bonds to the metallizing paste and the metallizing paste in turn bonds solidly to the piezoelectric stack 1. The thus-formed piezoelectric actuator can then be provided with terminal electrodes 12, 12° and its production is thus complete.

The metallizing paste from which the base metallization 20 is formed preferably comprises silver or a silver-palladium alloy, with which lead- or bismuth-containing glass frits, bismuth oxide, and/or lead-free glass powder are admixed, as adhesion promoters. These admixtures are necessary in order to establish a solid bond, which would otherwise not exist, with the completely sintered piezoelectric ceramic. So that the flexible metal electrode 25 will have a good mechanical bond and electrical connection with the base metallization 20, Invar wire which is coated with a layer of silver has proved itself.

In an alternative production method of the piezoelectric stack 1, the first layer 120 of the base metallization 20 is applied to the green body even before sintering. Next, the green body is sintered, so that the piezoelectric stack I forms, which already has the first layer 120 of the base metallization 20; this prevents the formation of the sintered skin in this region. Next, as described above and shown in FIG. 4, the second layer 220 of the base metallization 20 is applied. After the application of the flexible metal electrode 25, a firing process is again performed, for solidly bonding the second layer 220 of the base metallization 20 to the first layer and the flexible metal electrode 25 to the base metallization.

If the flexible metal electrode 25 comprises an Invar wire, then wire with a diameter of 50 to 100 μm is preferably used. If a metallizing paste that comprises silver or a silver-containing alloy is used, then the use of a silver-plated Invar wire is advantageous, since by that means the electrical and mechanical bond between the wire and the base metallization 20 is improved. If a metallizing paste whose basis is copper is used, then the Invar wire can correspondingly be coated with copper.

The application of a base metallization 20 in the form of a metal paste can be done for instance by printing, such as screen printing, or tampon printing, or some other suitable technique.

The firing of the metallizing paste to form the base metallization 20 is preferably done in a protective gas atmosphere, such as a nitrogen or argon atmosphere, but other noble gases can also be considered. This requires a metallizing paste based on an easily depolymerizable binder. Polymethacrylates are especially suitable for that purpose. Besides the metal powder, such as silver, silver-palladium, copper, nickel, or a mixture of these, the acrylate binder, and solvents, the metallizing paste also contains a glass powder. This glass is a preferably lead-free alkali-alkaline earth-boron silicate containing aluminum oxide (Al₂O₃), with a high SiO₂ proportion of greater than 50%. which is ground to a particle size in the range of d₅₀ (5 to 10 μm) and d₉₉ (to 35 μm) and which represents between 2 and 20% by volume of the inorganic solids of the paste.

If the metallizing paste is already applied before the sintering, then a silver or silver-palladium paste adapted to the sintering behavior in the ceramic, such as PZT ceramic, that does not contain glass but does contain a small amount of ceramic or metal oxide powder (ZrO₂, TiO₂) is required. In the case of actuators with copper inner electrodes, a variant with copper paste is also conceivable. The metallizing paste that is used for the second layer 220 of the base metallization 20 need not necessarily require a glass component in this case, since only metal surfaces have to be sintered with metal from the metallizing paste.

The piezoelectric actuator produced according to the invention thus has the advantage that it can be produced with relatively few process steps, which are economical. Unlike the situation when the flexible metal electrode 25 is soldered on, complex cleaning processes that make the piezoelectric actuator markedly more expensive are dispensed with. The piezoelectric actuator can be delivered to the subsequent process steps without further treatment.

1-22. (canceled)

23. A method for producing a piezoelectric actuator having a multiplicity of piezoelectric layers, between each of which a metal inner electrode is disposed, so that a piezoelectric stack is formed, and the inner electrodes are extended in alternation to different surface portions of the piezoelectric stack, comprising the steps of:
applying metalizing paste onto a part of each surface portion of a sintered piezoelectric stack;
placing a flexible metal electrode on the metalizing paste;
firing the piezoelectric actuator, so that the metalizing paste forms a base metallization which is bonded to the surface portion of the piezoelectric stack, whereupon the flexible metal electrode bonds to the base metallization by material engagement.

24. The method as defined by claim 23, wherein the metalizing paste is liquid while being applied to the piezoelectric stack.

25. The method as defined by claim 23, wherein the step of firing of the piezoelectric stack is performed at a temperature of more than 300° C., preferably at 700 to 800° C.

26. The method as defined by claim 24, wherein the step of firing is effected under protective gas, thereby preventing oxidation of the base metalization or of the flexible metal electrode.

27. The method as defined by claim 26, wherein the protective gas is nitrogen, argon, or another noble gas.

28. The method as defined by claim 23, wherein the metalizing paste is applied in two layers, and the first layer is applied directly to the piezoelectric stack.

29. The method as defined by claim 28, wherein the second layer of the base metalization covers from 20 to 80%, and preferably 30 to 70%, of the first layer.

30. The method as defined by claim 28, wherein the second layer of the base metalization is applied in parallel strips.

31. The method as defined by claim 29, wherein the second layer of the base metalization is applied in parallel strips.

32. The method as defined by claim 30, wherein the piezoelectric stack has an expansion direction, and wherein the strips of the second layer of the base metalization are slanted relative to a plane perpendicular to the expansion direction.

33. The method as defined by claim 28, wherein the second layer of the base metalization is not applied until the first layer has dried.

34. The method as defined by claim 28, wherein the flexible metal electrode is applied to the metalizing paste of the second layer of the base metalization, while the metalizing paste is still liquid.

35. The method as defined by claim 23, wherein the piezoelectric stack goes through the method steps prior to the step of applying the metalizing paste:
sintering of the piezoelectric stack;
sanding the surface portion of the piezoelectric stack at least in the part where the metalizing paste is to be applied, so that an electrical connection takes place between the metalizing paste and the inner electrodes which are extended to the surface in that part.

36. A method for producing a piezoelectric actuator having a multiplicity of piezoelectric layers, between each of which a metal inner electrode is disposed, so that a piezoelectric stack is formed, and the inner electrodes are extended in alternation to different portions of the piezoelectric stack, comprising the steps of:
applying a first layer of a metalizing paste to part of a surface of each portion of an unsintered piezoelectric stack embodied as a green body;
sintering the piezoelectric stack, whereupon the first layer of metalizing paste bonds to the surface of the piezoelectric stack and thus forms a first layer of a base metalization which makes an electrical connection with some of the inner electrodes;
applying a further layer of metalizing paste to the first layer of the base metalization;
placing a flexible metal electrode on the further layer of metalizing paste;
firing the piezoelectric actuator, so that the further layer of metalizing paste forms a second layer of the base metalization, whereupon the flexible metal electrode is bonded to the base metalization by material engagement.

37. The method as defined by claim 36, wherein the metalizing paste is liquid while being applied to the piezoelectric stack.

38. The method as defined by claim 36, wherein the step of firing of the piezoelectric stack is performed at a temperature of more than 300° C., preferably at 700 to 800° C.

39. The method as defined by claim 37, wherein the step of firing is effected under protective gas, thereby preventing oxidation of the base metalization or of the flexible metal electrode.

40. The method as defined by claim 39, wherein the protective gas is nitrogen, argon, or another noble gas.

41. The method as defined by claim 36, wherein the second layer of the base metalization covers from 20 to 80%, and preferably 30 to 70%, of the first layer.

42. The method as defined by claim 36, wherein the second layer of the base metalization is applied in parallel strips.

43. The method as defined by claim 41, wherein the second layer of the base metalization is applied in parallel strips.

44. The method as defined by claim 42, wherein the piezoelectric stack has an expansion direction, and wherein the strips of the second layer of the base metalization are slanted relative to a plane perpendicular to the expansion direction.

45. The method as defined by claim 41, wherein the second layer of the base metalization is not applied until the first layer has dried.

46. The method as defined by claim 36, wherein the flexible metal electrode is applied to the metalizing paste of the second layer of the base metalization, while the metalizing paste is still liquid.

47. A piezoelectric actuator having a multiplicity of piezoelectric layers, between each of which a metal inner electrode is disposed, so that a piezoelectric stack is formed, and the inner electrodes are extended in alternation to different portions of the surface of the piezoelectric stack, and having at least two outer electrodes, which are applied to the surface of the piezoelectric stack and which are each electrically connected to some of the inner electrodes, and the outer electrodes comprise a base metalization applied directly to the piezoelectric stack and a flexible metal electrode applied to the base metalization, wherein the flexible metal electrode is incorporated into the base metalization by firing thereof.

48. The piezoelectric actuator as defined by claim 47, wherein the base metalization includes two layers, a first layer being applied directly to the piezoelectric stack and a second layer covering only from 30 to 70% of the first layer.

49. The piezoelectric actuator as defined by claim 48, wherein the second layer is applied in strips to the first layer of the base metalization.

50. The piezoelectric actuator as defined by claim 49, wherein the strips of the second layer of the base metalization are embodied as inclined relative to a plane perpendicular to an axis of expansion of the piezoelectric stack.

51. The piezoelectric actuator as defined by claim 48, wherein the flexible metal electrode is connected electrically to the base metalization only at points where the second layer covers the first layer.

52. The piezoelectric actuator as defined by claim 47, wherein the flexible metal electrode is made from Invar.

53. The piezoelectric actuator as defined by claim 52, wherein the flexible metal electrode is made from Invar wire.

54. The piezoelectric actuator as defined by claim 52, wherein the flexible metal electrode is silver-plated.

55. The piezoelectric actuator as defined by claim 54, wherein the metal component of the base metalization is silver or an alloy that contains silver.
